(19) United States
(12) Patent Application Publication
(10) Pub. No.: US 2012/0139592 A1
(43) Pub. Date: Jun. 7, 2012

(54) Method and Apparatus for Frequency Synthesizing

(75) Inventors: Sun Bo, San Diego, CA (US); Jifeng Geng, San Diego, CA (US)

(73) Assignee: QUALCOMM Incorporated, San Diego, CA (US)

(21) Appl. No.: 12/961,779

(22) Filed: Dec. 7, 2010

(51) Int. Cl. H03L 7/08

(52) U.S. Cl. 327/156

(57) ABSTRACT

Systems and methods for frequency synthesis are disclosed. Exemplary embodiments of the digital frequency synthesizer can produce a fixed frequency and/or a modulated signal. An exemplary digital frequency synthesizer includes series-coupled delay cells, a linear feedback shift register, and an accumulator. The series-coupled delay cells generate, from an input clock signal, multiple clock edges corresponding to fractional clock periods. A linear feedback shift register selects clock edges to pass to a combinational logic circuit, based on a sign/enable control signal received from an accumulator and a clock signal received from the combinational logic circuit's output. The accumulator receives a control signal and controls the phase of the synthesizer output based upon the received control signal.

### FIELD OF DISCLOSURE

This disclosure relates to methods and systems for synthesizing a fixed frequency signal, as well as producing a modulated signal.

### BACKGROUND

Modern electronics often require multiple timing signals to clock a multitude of different signal processing circuits. Traditional circuits produce each of the required timing signals with a dedicated frequency synthesizer that modifies an input clock signal supplied by an oscillator. Each conventional frequency synthesizer contains an analog phase locked loop with an associated voltage controlled oscillator. Further, each frequency synthesizer occupies layout area on a semiconductor die, requires power, and is subject to coupled noise and effects of spurious radiation. Most traditional frequency synthesizers also require a filter capacitor that is external to the semiconductor die.

There are long-felt industry needs for frequency synthesizers that, compared to conventional devices, occupy less layout area on an integrated circuit die, have lower power consumption, have greater timing accuracy, have greater noise immunity, have faster lockup times, are located completely on the integrated circuit die, and modulate more accurately. Thus, there are needs to improve upon classic circuit designs and methods.

### SUMMARY

Exemplary embodiments are directed to systems and methods for synthesizing a signal having fixed frequency, as well as systems and methods for producing a modulated signal. The exemplary embodiments address the long-felt needs in the industry described herein.

Systems and methods for digital frequency synthesis are provided. Embodiments of the digital frequency synthesizer can produce a fixed programmable frequency and/or a modulated signal. The digital frequency synthesizer provides many benefits, for example, the digital frequency synthesizer saves area on a silicon die because it eliminates a need for separate frequency synthesizers to support processing of each signal path, such as a receive signal path, transmit signal path, diversity signal path, GPS signal path, etc. Among other benefits, the reduction in circuitry leads to reduced power demand, fewer intermodulation issues, and a lower component count that reduces production costs. The digital frequency synthesizer also provides greater timing accuracy and locks up in nanoseconds, which is faster than conventional phase locked loop and voltage controlled oscillator circuits. When used as a modulator, the digital frequency synthesizer provides direct phase and frequency modulation. Compared to conventional modulator designs, the digital frequency synthesizer modulates more accurately and provides a wider bandwidth.

In an embodiment, the digital frequency synthesizer includes multiple delay cells coupled in series. A clock signal is input to the delay cells. The delay cells sequentially delay the input clock signal. The outputs of the delay cells, as a group, provide a parallel output signal having a series of delayed edges of the input clock signal. The digital frequency synthesizer also includes a linear feedback shift register (LFSR) that has multiple registers coupled in series, and is configured to cycle a logic “1” in an endless loop. The outputs of the LFSR as a group also provide a parallel output signal. Respective parallel outputs from the delay cells and the LFSR are input to respective AND gates. Outputs of the AND gates are combined in an OR gate to produce the digital synthesized output signal. The digital synthesized output signal, in turn, clocks each register in the LFSR.

Also provided is a method of generating a digital synthesized signal. The method includes inputting a clock signal at a first frequency into a plurality of delay cells for generating and outputting a series of delayed edges of the clock signal. A modified version of the clock signal is input into an LFSR to enable respective portions thereof. The series of delayed edges and outputs of the respective portions of the LFSR are combined in a logic circuit to generate the synthesized signal.

### BRIEF DESCRIPTION OF THE DRAWINGS

The accompanying drawings are presented to aid in the description of the various embodiments and are provided solely for illustration of the embodiments and not limitation thereof.

FIG. 1 is a block diagram of an exemplary communication device having an exemplary digital frequency synthesizer.

FIG. 2A is a block diagram of the digital frequency synthesizer.

FIG. 2B is another block diagram of the digital frequency synthesizer, including an overlaid exemplary timing diagram.

FIG. 3 depicts a delay locked loop.

FIG. 4 is a schematic of a linear feedback shift register.

FIG. 5 is a schematic of a multiplexer/combiner.

FIG. 6 is a schematic of a fine delay control circuit.

FIG. 7 depicts a flowchart of a method of generating a synthesized signal.

### DETAILED DESCRIPTION

Aspects of the invention are disclosed in the following description and related drawings directed to specific embodiments of the disclosure. Alternate embodiments can be devised without departing from the scope of the invention. Additionally, well-known elements may not be described in detail or will be omitted so as not to obscure the relevant details of the various embodiments.

The word “exemplary” is used herein to mean “serving as an example, instance, or illustration.” Any embodiment described herein as “exemplary” is not necessarily to be construed as preferred or advantageous over other embodiments. Likewise, the term “embodiments” or “embodiments of the invention” does not require that all embodiments include a discussed feature, advantage or mode of operation.

The terminology used herein is for the purpose of describing particular embodiments only and is not intended to be limiting of various embodiments. As used herein, the singular forms “a,” “an,” and “the” are intended to include the plural forms as well, unless the context clearly indicates otherwise. It will be further understood that the terms “comprises,” “comprising,” “includes,” and/or “including,” when used herein, specify the presence of stated features, integers, steps, operations, elements, and/or components, but do not preclude the presence or addition of one or more other features, integers, steps, operations, elements, components, and/or groups thereof.

Further, many embodiments are described in terms of sequences of actions to be performed by, for example, elements of a computing device. It will be recognized that various actions described herein can be performed by specific circuits (e.g., application specific integrated circuits (ASICs)), by program instructions being executed by one or more processors, or by a combination of both. Additionally, the sequences of actions described herein can be considered to be embodied entirely within any form of computer readable storage medium having stored therein a corresponding set of computer instructions that upon execution would cause an associated processor to perform the functionality described herein. Thus, the various aspects of the invention can be embodied in a number of different forms, all of which have been contemplated to be within the scope of the claimed subject matter. In addition, for each of the embodiments described herein, the corresponding form of any such embodiments can be described herein as, for example, “logic configured to” perform the described action.

Systems and methods for frequency synthesis are provided. Frequency synthesis is the generation, from an input generated by a fixed frequency oscillator, of a signal having a frequency in a range of frequencies. The disclosed digital frequency synthesizer can multiply, divide, and mix frequencies. Embodiments of the digital frequency synthesizer can produce a fixed programmable frequency and/or a modulated signal. Among other benefits, the digital frequency synthesizer saves area on a silicon die because it eliminates a need for separate frequency synthesizers to support processing of each signal path, such as a receive path, transmit path, diversity path, GPS path, etc. Savings of silicon area is also realized through a reduced need for external filter devices. The reduced quantity of circuitry leads to reduced power demand, fewer intermodulation issues, and a lower component count that reduces fabrication costs. The digital frequency synthesizer also provides greater timing accuracy with lower noise than conventional designs. In addition, the digital frequency synthesizer also locks up faster than conventional phase locked loop and voltage controlled oscillator circuits. When used as a modulator, the digital frequency synthesizer provides direct phase and frequency modulation. Compared to conventional modulators, the digital frequency synthesizer modulates more accurately and provides a wider bandwidth.

The digital frequency synthesizer functions based on direct digital synthesis and frequency to phase translation. A delay locked loop (DLL) generates precise, substantially equally delayed clock edges. The DLL has a quantity of “n” delay cells which each delay the input clock by a delay unit “n.” Selected delayed clock edges are passed to a combiner, which outputs a synthesized digital clock as the digital frequency synthesizer output. The clock edges can be selected to maintain the phase of the digital frequency synthesizer's output as fixed, relative to the input clock. For example, when the delayed clock edges are selected for every clock period, the frequency of the digital frequency synthesizer output equals approximately:

$$\frac{1}{1 \pm ( \frac{1}{n} ) * {T}_{lo}}$$

where Tₗₒ is the period of the input clock/local oscillator. As a further example, when the delayed clock edges are selected for every fractional clock period “1/m,” the frequency of the digital frequency synthesizer output equals approximately:

$$\frac{1}{1 \pm ( \frac{1}{n * m} ) * {T}_{lo}}$$

Thus, when n=8, the maximum output frequency range can vary from the input clock frequency by approximately ±12.5%.

In the digital frequency synthesizer, the clock edges are selected by a multiplexer controlled by a phase control signal from an accumulator. The accumulator integrates an input frequency control signal to create the phase control signal. Thus, the frequency control signal determines the phase of the digital frequency synthesizer output. If the frequency control signal is fixed, then the frequency of the digital frequency synthesizer output is fixed. If the frequency control signal varies, then the frequency of the digital frequency synthesizer output varies accordingly (i.e., the frequency control signal modulates the clock signal input to the digital frequency synthesizer).

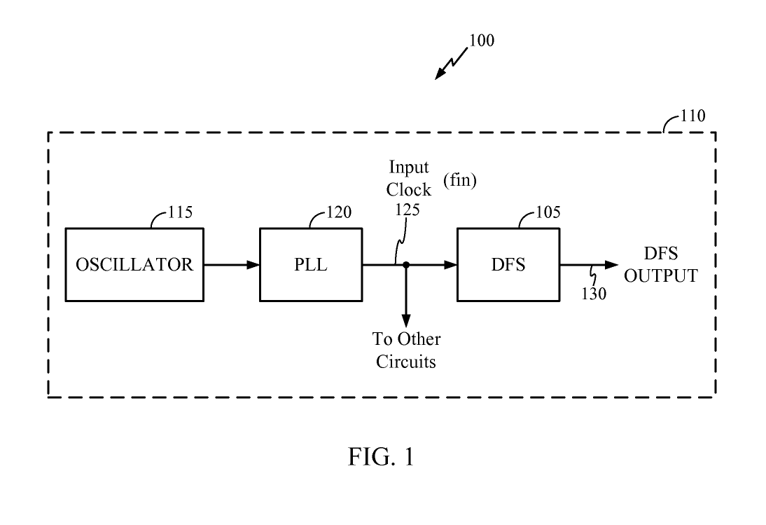

FIG. 1 is a block diagram of an exemplary communication device 100 having a digital frequency synthesizer (DFS) 105. Examples of the communication device 100 include a wireless communication device such as a cellular, cordless, Personal Communication System, mobile phone, or other type of wireless telephone device. Further examples of the communication device 100 include a baseband circuit, a transmitter; a receiver; a transceiver; a pager; a wireless personal digital assistant; a settop box; a music player; a video player; an entertainment unit; a notebook computer with wireless access; a wireless mobile device; a two-way radio; a walkie-talkie; a mobile station, a multiple input, multiple output (MIMO) device; navigation device; a Global Positioning System receiver; a fixed location data units such as meter reading equipment, or any other device that stores or retrieves data or computer instructions, or any combination thereof. Additional examples of the communication device 100 include a polar transmitter, such as those found in narrowband polar GSM and EDGE systems, as well as wideband devices, such as WCDMA, BT, and WLAN devices. In an example, at least a part of the DFS 105 is integrated in a semiconductor 110. The DFS 105 can be fabricated using CMOS technology.

An oscillator 115, for example, a temperature-compensated crystal oscillator (TCXO), generates a reference clock signal. The reference clock signal is processed by a phase locked loop (PLL) 120 to stabilize the phase and frequency of the reference clock signal, and to form an input clock signal 125 having a frequency (Fᵢₙ). As shown, the input clock signal 125 can be used by circuits that require a clock signal, other than the DFS 105, in the communication device 100. The DFS 105 produces a DFS output 130 that is a digital, frequency synthesized signal. The DFS 105 is described below in further detail.

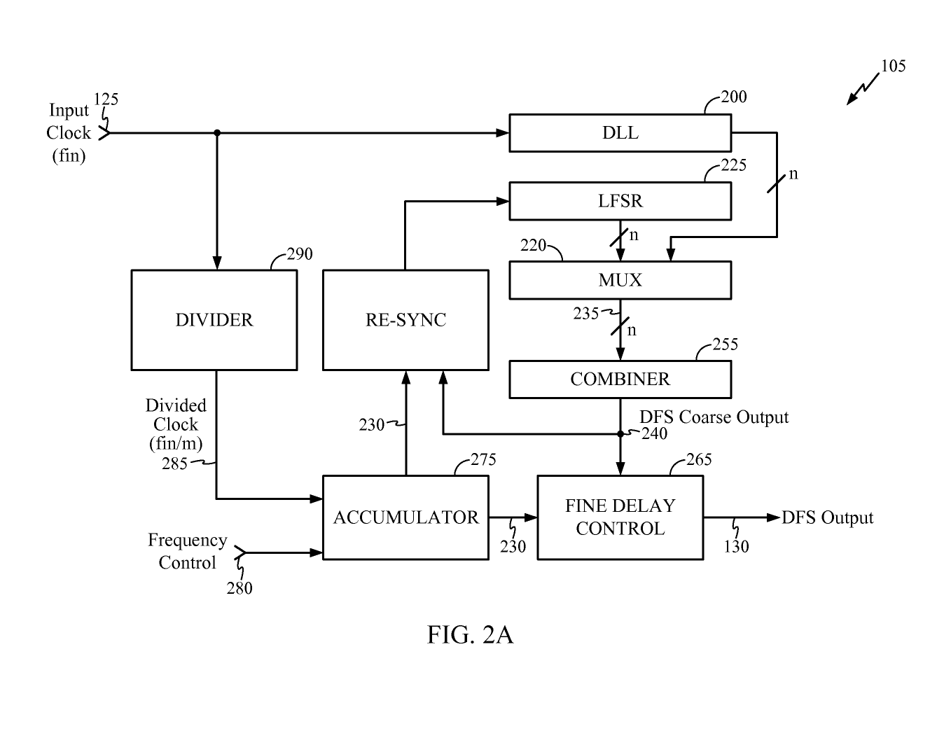

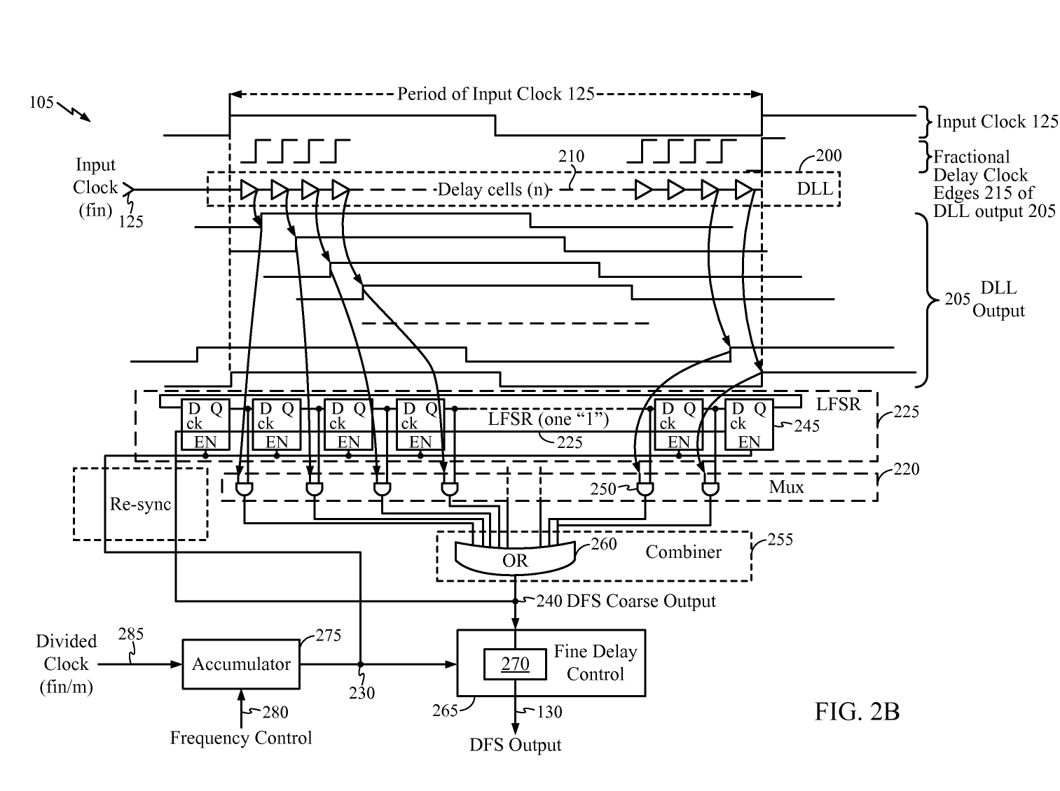

FIGS. 2A-2B describe a high-level block diagram of the DFS 105, including an overlaid exemplary timing diagram. The DFS 105 receives the input clock signal 125 at a conventional delay locked loop (DLL) 200. The DLL 200 generates a parallel DLL output (CK_{1 to n}) 205, with each output having the input clock signal 125 fractionally delayed relative to the other outputs. The parallel DLL output 205 is produced by sequentially delaying the input clock signal 125 with a quantity of “n” serial-coupled delay cells 210, as shown in FIG. 2B. The outputs of the delay cells 210, as a group, provide the parallel DLL output 205. Thus, the DLL 200 provides fractionally delayed clock edges 215 of the input clock signal 125 to a multiplexer 220.

A bidirectional linear feedback shift register (LFSR) 225 provides another input to the multiplexer 220. The LFSR 225 converts a phase control signal 230 to a parallel LFSR output signal (Qₘ) 235. If the phase control signal 230 is constant, then the DFS output 130 has a fixed frequency. If the phase control signal 230 varies, then the DFS output 130 frequency is modulated accordingly. The LFSR 225 also locks the parallel LFSR output signal (Qₘ) 235 to a DFS coarse output 240 because the LFSR's registers 245 are clocked with the DFS coarse output 240. The parallel LFSR output signal (Qₘ) 235 is forwarded to the multiplexer 220.

The multiplexer 220 selects a delayed clock signal from a single DLL output in the parallel DLL output 205 based on the parallel LFSR output signal (Qₘ) 235. The selection is made with AND gates 250. The multiplexer 220 provides the selected delayed clock signal to a combiner 255 via a parallel output.

The combiner 255 combines the parallel output of the multiplexer 220 to form the DFS coarse output 240. The combiner 255 outputs, as the DFS coarse output 240, any input signal provided by any line in the parallel output of the multiplexer 220. In an exemplary circuit, an OR gate 260 can be used as the combiner 255. The DFS coarse output 240 can optionally be further refined with a fine delay control circuit 265, or is output as the DFS output 130.

The fine delay control circuit 265 improves the timing accuracy of the DFS coarse output 240. The fine delay control circuit 265 includes at least one additional delay locked loop 270 to process the DFS coarse output 240 and produce the DFS output 130. The fine delay control circuit 265 is controlled by an accumulator 275.

The accumulator 275 receives a frequency control signal 280 and a divided clock 285 having a frequency of (Fᵢₙ)/m, where “m” is a fractional relation of the synthesized signal to the clock signal. Dividing the clock is optional, i.e., “m” can equal one. In an example, the frequency control signal 280 has a frequency between substantially 62.5 MHz and substantially 250 MHz. The frequency control signal 280 can also be digitally pre-compensated to linearize the response of the DFS 105.

The accumulator 275 provides a re-synchronizing phase control signal 230 to the LFSR 225 and the fine delay control circuit 265 that is based on the frequency control signal 280. The phase control signal 230 enables the LFSR registers 245. Every overflow of the accumulator 275 represents an integer phase step. Timing of the phase control signal 230 relative to the frequency of the fractionally delayed clock edges 215 determines the selection rate of the fractionally delayed clock edges 215 by the multiplexer 220. The digital bitwidth of the accumulator 275 determines the frequency resolution of the DFS 105 as follows:

$$\frac{{F}_{in}}{n * m * bitwidth}$$

where Fᵢₙ is the frequency of the input clock signal 125, “n” is the number of delay cells 210 and delay units (e.g., 8), and “m” is the fractional relation of the divided clock 285 to the clock signal (e.g., 4). An exemplary bitwidth is 28 bits. It is important to note that delay of the phase control signal 230 sent to the LFSR 225 due to the accumulator 275 should be compensated.

A divider 290 is an optional circuit that divides the input clock signal 125 by the factor “m” to provide the divided clock 285 to the accumulator 275.

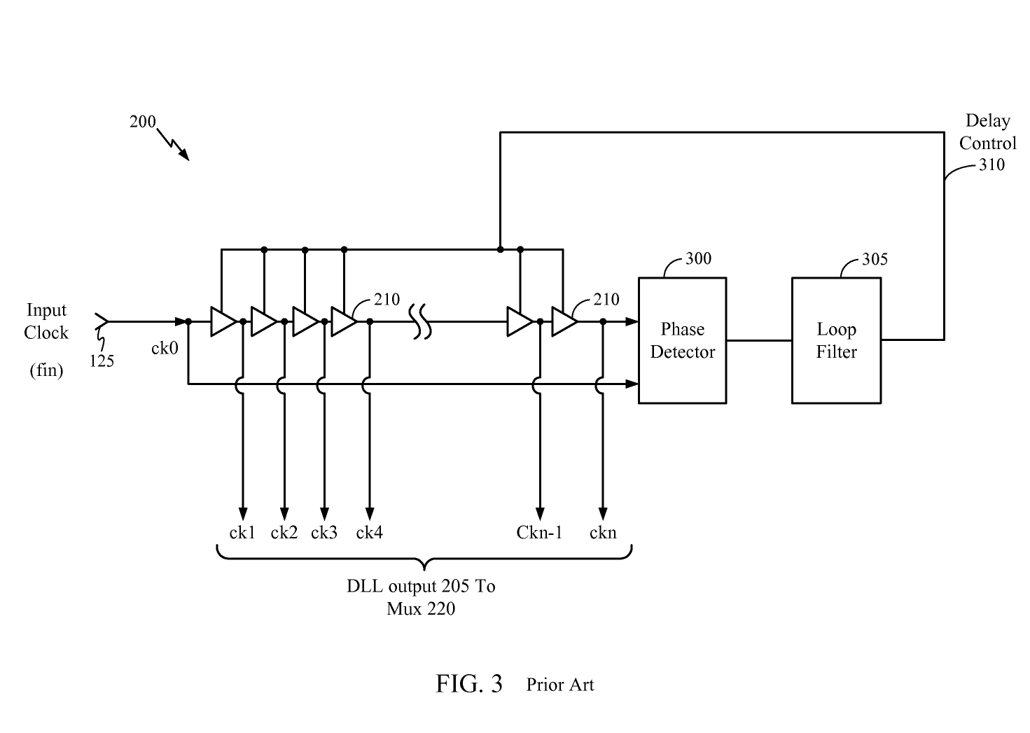

FIG. 3 depicts the conventional DLL 200 in further detail. The DLL 200 generates the parallel DLL output (CK_{1 to n}) 205 with each output line having the input clock signal 125 fractionally delayed relative to the other output lines. The DLL output 205 is produced by sequentially delaying the input clock signal 125 with a quantity of “n” serial-coupled delay cells 210, which each delay the input clock signal 125 by a delay unit “n.” The DLL output 205 is stabilized using closed-loop feedback. Stabilization is critical to providing the enhanced noise performance of the DFS 105. The output of the last delay cell 210 is input to a phase detector 300. The input clock signal 125 is also input to the phase detector 300. The phase detector 300 compares the phases of the two signals and generates an error signal based upon the difference. The error filtered by a loop filter 305 to form a delay control 310. The delay control 310 enables and disables the delay cells 210 to stabilize the phase of the DLL output 205 relative to the input clock signal 125. The DLL output 205 is provided to the multiplexer 220.

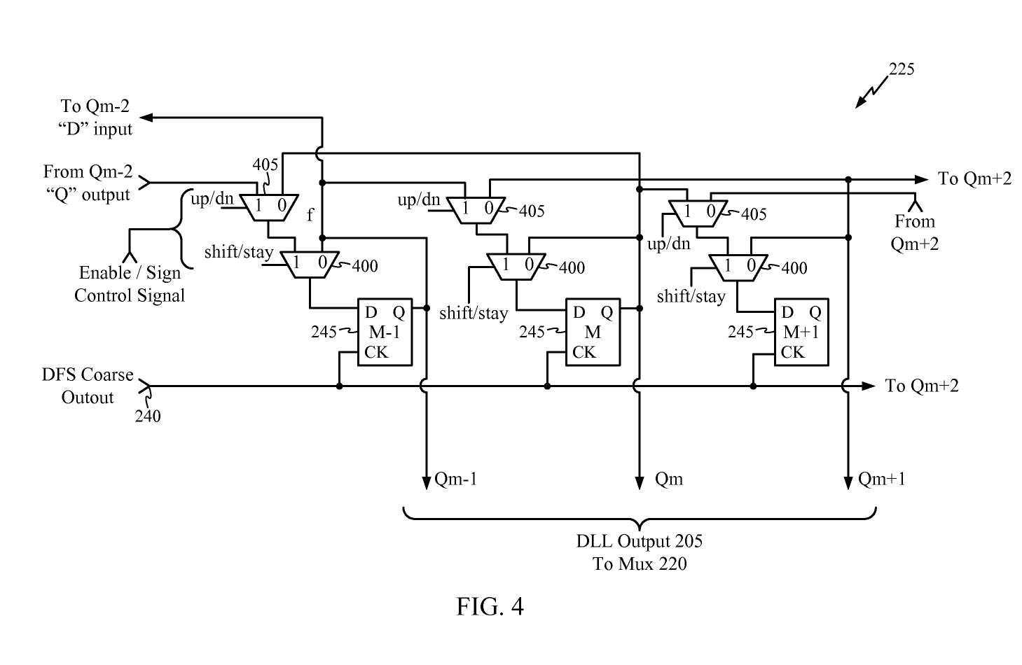

FIG. 4 is a schematic of the LFSR 225. The LFSR 225 converts the phase control signal 230 to a parallel LFSR output signal (Qₘ) 235. If the phase control signal 230 is constant, then the DFS output 130 has a fixed frequency. If the phase control signal 230 varies, then the DFS output 130 frequency is modulated accordingly.

The LFSR 225 includes LFSR registers 245, identified in FIG. 4 as M_{n±x}, which are configured to cycle a logic “1” bit in an endless loop. The LFSR registers 245 are clocked by the DFS coarse output 240. A “Q” output of each LFSR register 245 is coupled to a “D” input of a sequential LFSR register 245 and a “D” input of a preceding LFSR register 245 via two daisy-chained multiplexers 400, 405 that direct the cycled bit to one of the two LFSR registers 245. The multiplexers 400, 405 direct the cycled bit based on the phase control signal 230 received from the accumulator 275. Referring to FIGS. 2R and 4, when the LFSR 225 is enabled to shift the bit from right to left, the DFS output 130 has a higher frequency. When the LFSR 225 is enabled to shift the bit from left to right, the DFS output 130 has a lower frequency.

During operation, the single logic “1” bit is cycled through the loop formed by the LFSR registers 245. The phase control signal 230 determines both a direction in which the logic “1” is cycled through the loop of LFSR registers 245, as well as if the logic “1” is shifted or held constant. The output of the LFSR registers 245 in the LFSR 225 produce a parallel LFSR output signal (Qₘ) 235 that is locked to the DFS coarse output 240. The parallel LFSR output signal (Qₘ) 235 is forwarded to the multiplexer 220.

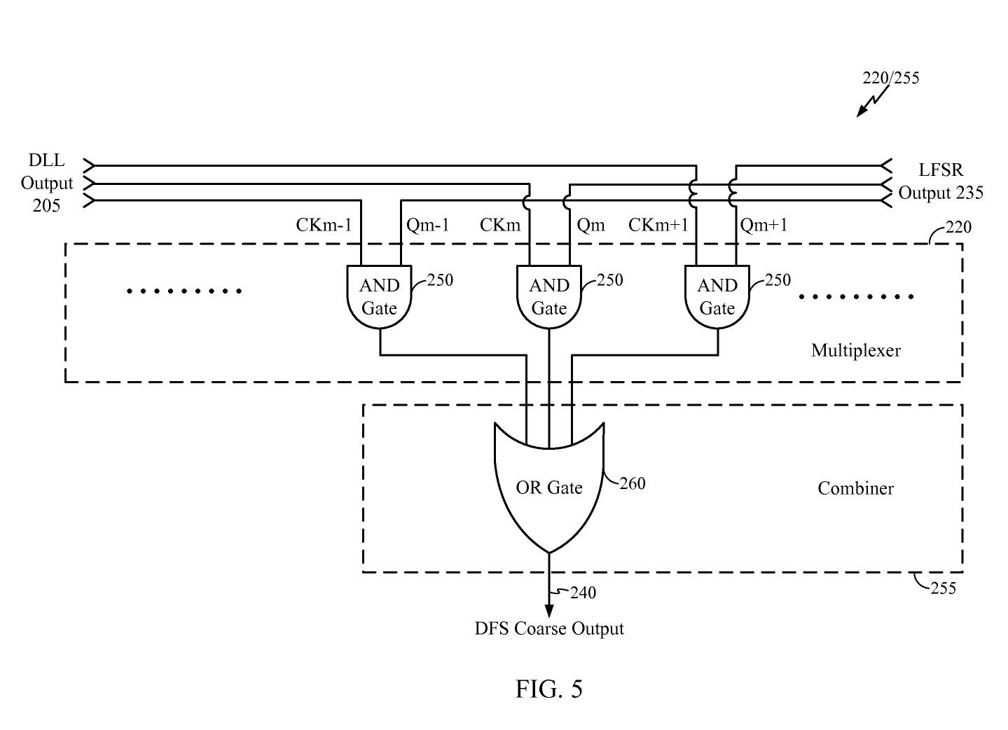

FIG. 5 is a schematic of a the multiplexer 220 and the combiner 255. The multiplexer 220 selects a delayed clock signal from an output in the parallel DLL output 205, based on the parallel LFSR output signal (Qₘ) 235. The selection is made with the AND gates 250 to which both the DLL output (CK_{1 to n}) 205 and the parallel LFSR output signal (Qₘ) 235 are input. The multiplexer 220 provides the selected delayed clock signal to the combiner 255 via a parallel output.

The combiner 255 combines the parallel output of the multiplexer 220 to form the DFS coarse output 240. The combiner 255 outputs, as the DFS coarse output 240, any input signal provided by any line in the parallel output of the multiplexer 220. In an example, as depicted in FIG. 5, the OR gate 260 can be used as the combiner 255.

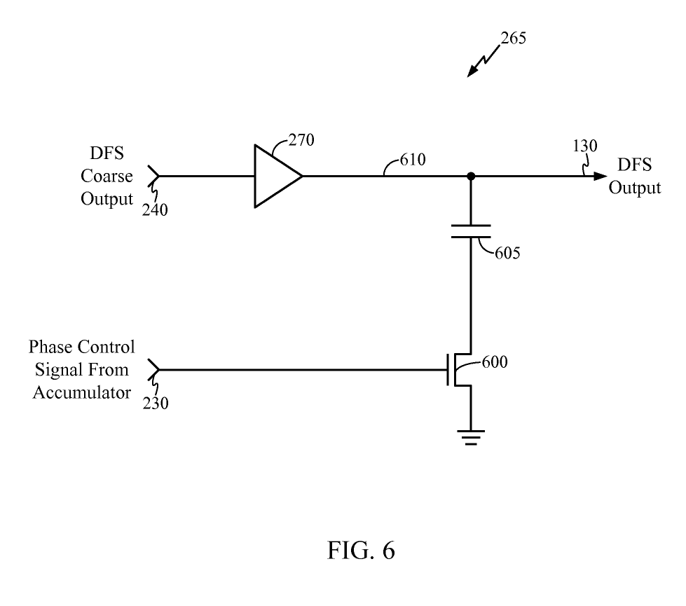

FIG. 6 is a schematic of a fine delay control circuit 265. The fine delay control circuit 265 improves the timing accuracy of the DFS coarse output 240. The fine delay control circuit 265 includes the additional delay locked loop(s) 270. The additional delay locked loop(s) 270 produce(s) the DFS output 130 by delaying the DFS coarse output 240. The line delay control circuit 265 is controlled by the phase control signal 230 from the accumulator 275. The phase control signal 230 cycles a switch 600 to selectively apply a low pass filter 605 to the additional delay locked loop(s) output 610 to generate the DFS output 130. In an example, the phase control signal 230 comprises multiple conductors, with individual conductors coupled to a respective switch 600 in a plurality of switches. Each switch 600 in the plurality of switches is coupled to a respective low pass filter 605.

In a non-limiting example where the DFS 105 provides a DFS output 130 having a fixed frequency equal to the frequency of the input clock signal 125, the input clock signal 125 has a frequency of four gigahertz, the divider 290 divides the input clock signal 125 by an “m” value equal to four, thus the divided clock 285 has a frequency of 1 GHz. The DLL 200 has eight delay units, yielding a delay time for each delay cell 210 of 31.25 picoseconds. The accumulator 275 has a bitwidth of twenty-eight hits and provides the phase control signal 230 at one gigahertz to the LFSR 225. The fine delay control circuit 265 has two additional series-coupled DLLs 270. Accordingly, the DFS coarse output 240 and the DFS output 130 have a frequency of four gigahertz with an accuracy of 0.122 picoseconds. All numerical data in this example is approximate.

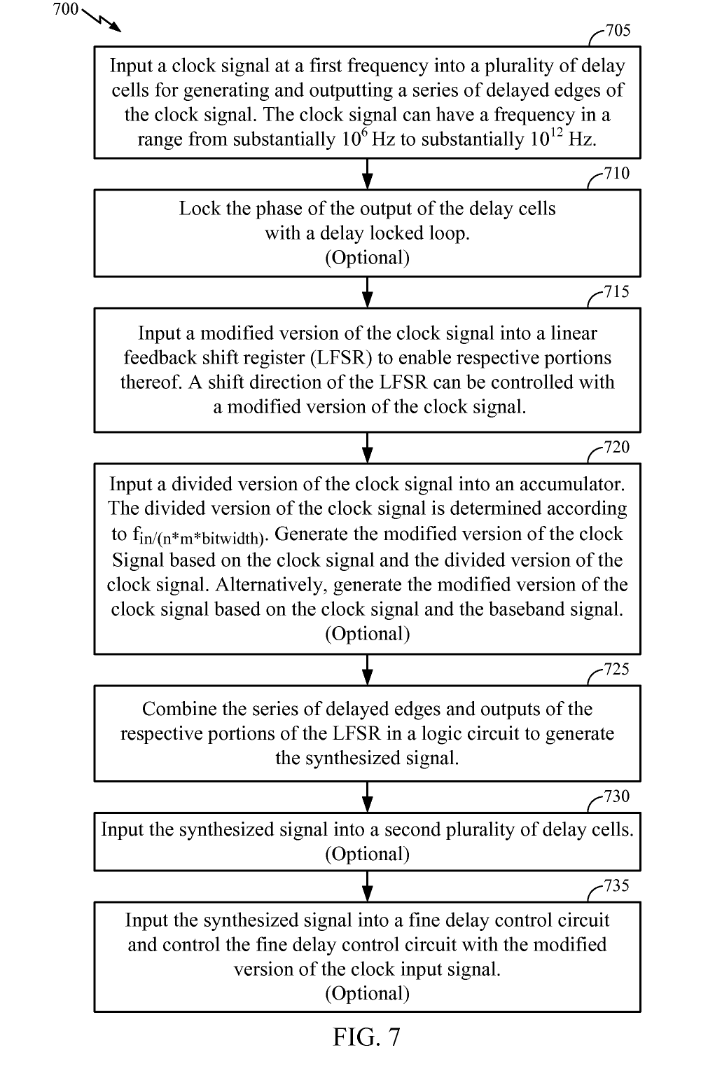

FIG. 7 depicts a flowchart of a method of generating a synthesized signal 700. The method of generating a synthesized signal 700 can be executed at least in part using the devices described herein, such as the communication device 100 and DFS 105. The method of generating a synthesized signal 700 is not limited to the devices described herein, and can be performed by any suitable device.

In step 705, an input clock signal at a first frequency (Fᵢₙ) is input into a plurality of delay cells for generating and outputting a series of delayed edges of the clock signal. In an example, the clock signal can have a frequency in a range from substantially 10⁶ Hz to substantially 10¹² Hz.

In step 710, the phase of the output of the delay cells is locked with a delay locked loop. Step 710 is optional.

In step 715, a modified version of the clock signal is input into a linear feedback shift register (LFSR) to enable respective portions thereof. Enabling respective portions of the LFSR can comprise controlling a shift direction of the LFSR with the modified version of the clock signal.

In step 720, a divided version of the input clock signal is input into an accumulator. Dividing the clock is optional, the input clock signal can be input, undivided, to the accumulator. The divided version of the input clock signal is determined according to F_{in/(n*m*bitwidth)}. The factor “n” is an integer relation of the synthesized signal to the input clock signal, “m” is the fractional relation of the synthesized signal to the input clock signal, and is determined first. “Bitwidth” is the accumulator's digital bitwidth. If “m” equals one, the clock is not divided. The modified version of the clock signal is generated based on the input clock signal and the divided version of the clock signal. Alternatively, the modified version of the input clock signal is generated based on the divided version of the clock signal and a baseband signal. Step 720 is optional.

In step 725, the series of delayed edges and outputs of the respective portions of the LFSR 225 is combined in a logic circuit to generate the synthesized signal.

In step 730, the synthesized signal is input into a second plurality of delay cells 210 to improve the accuracy of the synthesized signal. Step 730 is optional.

In step 735, the synthesized signal is input into a fine delay control circuit 265. The fine delay control circuit is controlled with the modified version of the input clock signal. Step 735 is optional.

Those of skill in the art will appreciate that information and signals can be represented using any of a variety of different technologies and techniques. For example, data, instructions, commands, information, signals, bits, symbols, and chips that can be referenced throughout the above description can be represented by voltages, currents, electromagnetic waves, magnetic fields or particles, optical fields or particles, or any combination thereof.

Further, those of skill in the art will appreciate that the various illustrative logical blocks, modules, circuits, and algorithm steps described in connection with the embodiments disclosed herein can be implemented as electronic hardware, computer software, or combinations of both. To clearly illustrate this interchangeability of hardware and software, various illustrative components, blocks, modules, circuits, and steps have been described above generally in terms of their functionality. Whether such functionality is implemented as hardware or software depends upon the particular application and design constraints imposed on the overall system. Skilled artisans can implement the described functionality in varying ways for each particular application, but such implementation decisions should not be interpreted as causing a departure from the scope of the invention.

The methods, sequences and/or algorithms described in connection with the embodiments disclosed herein can be embodied directly in hardware, in a software module executed by a processor, or in a combination of the two. A software module can reside in RAM memory, flash memory, ROM memory, EPROM memory, EEPROM memory, registers, hard disk, a removable disk, a CD-ROM, or any other form of storage medium known in the art. An exemplary storage medium is coupled to the processor such that the processor can read information from, and write information to, die storage medium. In the alternative, the storage medium can be integral to the processor.

Accordingly, an embodiment can include a computer readable media embodying a method for synthesizing a frequency. Further, it will be appreciated that the various embodiments are not limited to illustrated examples and any means for performing the functionality described herein are included in the embodiments.

While the foregoing disclosure shows illustrative embodiments, it should be noted that various changes and modifications could be made herein without departing from the scope of the invention as defined by the appended claims. The functions, steps and/or actions of the method claims in accordance with the embodiments described herein need not be performed in any particular order. Furthermore, although elements of the various embodiments may be described or claimed in the singular, the plural is contemplated unless limitation to the singular is explicitly stated.

What is claimed is:

1. A frequency synthesizer, comprising:
a plurality of series-coupled delay cells;
a linear feedback shift register (LFSR) including a plurality of registers;
a plurality of AND gates, each AND gate having a first input coupled to an output of a respective delay cell and a second input coupled to an output of a respective register; and
an OR gate having inputs coupled to each AND gate output, wherein the OR
gate output is coupled to a clock input of each register.

2. The frequency synthesizer of claim 1, wherein the plurality of series-coupled delay cells is a part of a delay locked loop.

3. The frequency synthesizer of claim 1, wherein the LFSR comprises a multiplexer having an output coupled to an input of a register in the plurality of registers, and configured to control a shift direction of the LFSR.

4. The frequency synthesizer of claim 1, wherein the LFSR comprises a multiplexer having an output coupled to an input of a register in the plurality of registers, and configured to disable shifting of data in the LFSR.

5. The frequency synthesizer of claim 1, further comprising an accumulator coupled to an enable input of each of the registers.

6. The frequency synthesizer of claim 1, further comprising a second plurality of series-coupled delay cells having an input coupled to the OR gate output.

7. The frequency synthesizer of claim 6, further comprising:
a capacitor and a transistor series-coupled between the OR gate output and ground; and
an accumulator having an output coupled to control the transistor.

8. The frequency synthesizer of claim 1, further comprising an oscillator coupled to an input of the plurality of series-coupled delay cells.

9. The frequency synthesizer of claim 1, further comprising a transmitter coupled to an output of the OR gate.

10. The frequency synthesizer of claim 1, further comprising a receiver coupled to an output of the OR gate.

11. A transmitter comprising the frequency synthesizer of claim 1.

12. A receiver comprising the frequency synthesizer of claim 1.

13. The frequency synthesizer of claim 1, wherein at least a part of the frequency synthesizer is integrated in a semiconductor die.

14. The frequency synthesizer of claim 1, further comprising a device, selected from the group consisting of a set top box, music player, video player, entertainment unit, navigation device, communications device, personal digital assistant (PDA), fixed location data unit, and a computer, into which the frequency synthesizer is integrated.

15. A method of generating a synthesized signal, comprising:
inputting a clock signal at a first frequency into a plurality of delay cells for generating and outputting a series of delayed edges of the clock signal;
inputting a modified version of the clock signal into a linear feedback shift register (LFSR) to enable respective portions thereof; and
combining the series of delayed edges and outputs of the respective portions of the LFSR in a logic circuit to generate the synthesized signal.

16. The method of claim 15, wherein the clock signal has a frequency in a range from substantially 10⁶ Hz to substantially 10¹² Hz.

17. The method of claim 15, wherein enabling respective portions of the LFSR comprises controlling a shift direction of the LFSR with the modified version of the clock signal.

18. The method of claim 15, further comprising locking the phase of the output of the delay cells with a delay locked loop.

19. The method of claim 15, further comprising inputting the synthesized signal into a second plurality of delay cells.

20. The method of claim 15, wherein inputting the modified version of the clock signal further comprises:
inputting the clock signal into an accumulator;
inputting a divided version of the clock signal into the accumulator, wherein the divided version of the clock signal is determined according to f_{in/(n*m*bitwidth)}, wherein n is an integer relation of the synthesized signal to the clock signal, m is a fractional relation of the synthesized signal to the clock signal, and bitwidth is the accumulator's digital bitwidth; and
generating the modified version of the clock signal, based on the clock signal and the divided version of the clock signal.

21. The method of claim 20, further comprising:
inputting the synthesized signal into a fine delay control circuit; and
controlling the fine delay control circuit with the modified version of the clock signal.

22. The method of claim 15, wherein inputting the modified version further comprises:
inputting the clock signal into an accumulator;
inputting a baseband signal into the accumulator; and
generating the modified version of the clock signal, based on the clock signal and the baseband signal.

23. The method of claim 22, further comprising:
inputting the synthesized signal into a fine delay control circuit; and
controlling the fine delay control circuit with the modified version of the clock signal.

24. A system to generate a synthesized signal, comprising:
means for inputting a clock signal at a first frequency into a plurality of delay cells for generating and outputting a series of delayed edges of the clock signal;
means for inputting a modified version of the clock signal into a linear feedback shift register (LFSR) to enable respective portions thereof; and
means for combining the series of delayed edges and outputs of the respective portions of the LFSR in a logic circuit to generate the synthesized signal.

25. The system of claim 24, wherein the clock signal has a frequency in a range from 10⁹ Hz to 10¹² Hz.

26. The system of claim 24, further comprising means for enabling respective portions of the LFSR comprising means for controlling a shift direction of the LFSR with the modified version of the clock signal.

27. The system of claim 24, further comprising means for locking the phase of the output of the delay cells with a delay locked loop.

28. The system of claim 24, further comprising means for inputting the synthesized signal into a second plurality of delay cells.

29. The system of claim 24, wherein the means for inputting the modified version of the clock signal further comprises:
means for inputting the clock signal into an accumulator;
means for inputting a divided version of the clock signal into the accumulator, wherein the divided version of the clock signal is determined according to f_{(in/n*m*bitwidth)}; wherein n is an integer relation of the synthesized signal to the clock signal, m is a fractional relation of the synthesized signal to the clock signal, and bitwidth is the accumulator's digital bitwidth; and
means for generating the modified version of the clock signal, based on the clock signal and the divided version of the clock signal.

30. The system of claim 29, further comprising:
means for inputting the synthesized signal into a fine delay control circuit; and
means for controlling the fine delay control circuit with the modified version of the clock signal.

31. The system of claim 24, wherein the means for inputting the modified version further comprises:
means for inputting the clock signal into an accumulator;
means for inputting a baseband signal into the accumulator; and
means for generating the modified version of the clock signal, based on the clock signal and the baseband signal.

32. The system of claim 31, further comprising:
means for inputting the synthesized signal into a fine delay control circuit; and
means for controlling the fine delay control circuit with the modified version of the clock signal.
